(19) United States
(12) Patent Application Publication
(10) Pub. No.: US 2016/0027833 A1
(43) Pub. Date: Jan. 28, 2016

(54) SEMICONDUCTOR DEVICE AND METHOD FOR MANUFACTURING THE SAME

(71) Applicant: Kabushiki Kaisha Toshiba, Tokyo (JP)

(72) Inventors: Masaaki Yamamoto, Oita Oita (JP); Kentaro Imamizu, Oita Oita (JP); Mokuji Kageyama, Oita Oita (JP)

(21) Appl. No.: 14/641,169

(22) Filed: Mar. 6, 2015

(30) Foreign Application Priority Data
Jul. 22, 2014 (JP) 2014-149255

(51) Int. Cl. H01L 27/146; H01L 31/18

(52) U.S. Cl. CPC H01L 27/14636; H01L 27/1463; H01L 27/1464; H01L 27/14683; H01L 31/1892

(57) ABSTRACT

According to one embodiment, a semiconductor device includes a semiconductor layer including a first plane and a second plane facing the first plane. A semiconductor element is formed in the semiconductor layer. The semiconductor layer includes a separation region formed to extend from the first plane to the second plane. The separation region surrounds a region where the semiconductor element is formed. The separation region includes a first separation region formed from the first plane of the semiconductor layer toward an interior of the semiconductor layer, and a second separation region formed from the second plane of the semiconductor layer to the first separation region.

### CROSS-REFERENCE TO RELATED APPLICATIONS

This application is based upon and claims the benefit of priority from Japanese Patent Application No. 2014-149255, filed on Jul. 22. 2014; the entire contents of which are incorporated herein by reference.

### FIELD

Embodiments described herein relate generally to a semiconductor device and a method for manufacturing the same.

### BACKGROUND

Conventionally, a back side illumination type CMOS image sensor is formed through steps of laminating a semiconductor substrate, which includes a semiconductor layer formed with a photoelectric conversion element, and a supporting substrate that supports the same, and thinning the semiconductor substrate after the lamination.

When thinning the semiconductor substrate, a film thickness of the semiconductor layer formed with the photoelectric conversion element may vary due to the variation of the relevant step, and the sensitivity of the rear surface irradiation type CMOS image sensor may vary. Furthermore, a technique of enhancing an insulating property between a region formed with the photoelectric conversion element and other regions, and suppressing a leak current is desired.

### BRIEF DESCRIPTION OF THE DRAWINGS

FIG. 1 is a view schematically illustrating a cross-sectional structure of a semiconductor device of a first embodiment;

FIG. 2 is a perspective view schematically illustrating the cross-sectional structure of the semiconductor device of the first embodiment;

FIGS. 3A to 3I are views illustrating one embodiment of a method for manufacturing the semiconductor device;

FIGS. 4A to 4I are views illustrating one embodiment of the method for manufacturing the semiconductor device.

### DETAILED DESCRIPTION

According to the present embodiment, a semiconductor device includes a semiconductor layer with a first plane and a second plane opposing the first plane. The semiconductor layer is formed with a semiconductor element. The semiconductor layer includes a separation region that extends from the first plane to the second plane. The separation region surrounds a region where the semiconductor element is formed. The separation region includes a first separation region formed from the first plane of the semiconductor layer toward the interior of the semiconductor layer, and a second separation region formed from the second plane of the semiconductor layer to the first separation region.

Exemplary embodiments of the semiconductor device and the method for manufacturing the same will be explained below in detail with reference to the accompanying drawings. The present invention is not limited to the following embodiments.

### First Embodiment

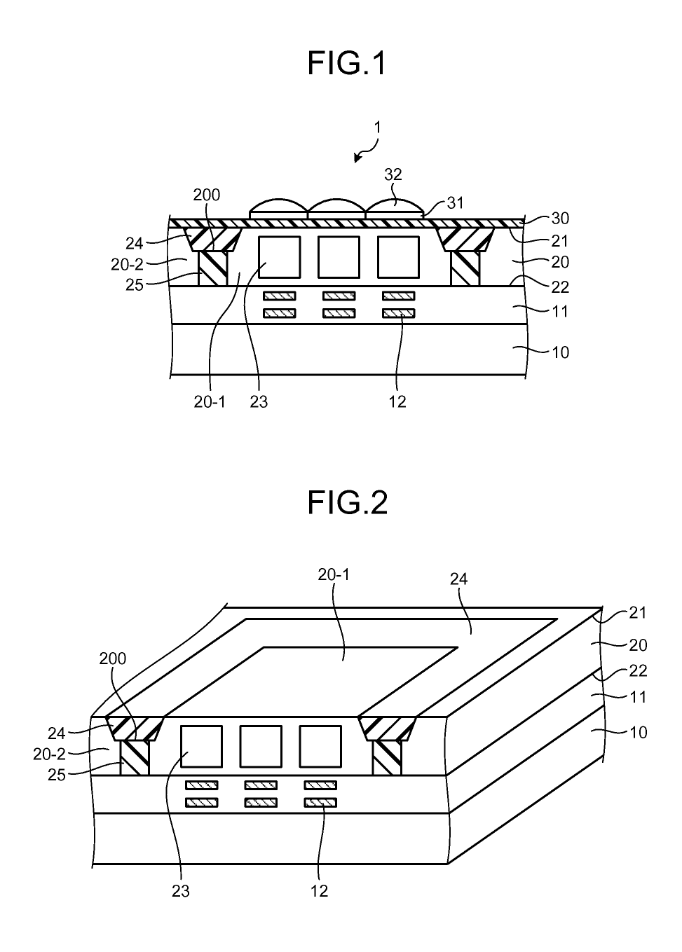

FIG. 1 is a view schematically illustrating a cross-sectional structure of a semiconductor device of a first embodiment. A semiconductor device 1 includes a supporting substrate 10. The supporting substrate 10 is, for example, configured by a semiconductor substrate. An insulating film 11 that makes contact with the front surface of the supporting substrate 10 is disposed on the supporting substrate 10. The insulating film 11 is, for example, configured by a silicon dioxide film. A predetermined wiring 12 is formed in the insulating film 11. The wiring 12 is, for example, configured by a metal film.

A semiconductor layer 20 is disposed on the insulating film 11. The semiconductor layer 20 includes a first plane 21 and a second plane 22. The semiconductor layer 20 is formed with a first separation region 24 and a second separation region 25. For example, the first separation region 24 has a shape in which the width is wide on the first plane 21 side and becomes narrower toward the interior of the semiconductor layer 20, where a cross-sectional shape orthogonal to a longitudinal direction (direction orthogonal to the plane of drawing) is a trapezoid. The second separation region 25 makes contact with the second plane 22 on a lower part side, and makes contact with the first separation region 24 at a connecting section 200 on an upper part side. In other words, the second separation region 25 is formed from the second plane 22 to the first separation region 24. The first separation region 24 and the second separation region 25 form a separation region extending from the first plane 21 to the second plane 22 of the semiconductor layer 20. For example, a width of the second separation region 25 orthogonal to a longitudinal direction is narrower than a width of the first separation region 24 orthogonal to a longitudinal direction. A region where the semiconductor element (not illustrated) can be formed in the semiconductor layer 20 can be widened by narrowing the width of the second separation region 25.

A photoelectric conversion element 23, for example, a photodiode is formed in the semiconductor layer 20. The first separation region 24 and the second separation region 25 are formed to surround a region 20-1 (hereinafter referred to as a pixel region) where the photoelectric conversion element 23 is formed. The first separation region 24 and the second separation region 25 form the separation region extending from the first plane 21 to the second plane 22 of the semiconductor layer 20, which separation region surrounds the pixel region 20-1 so that the pixel region 20-1 can be electrically separated from other regions 20-2 (hereinafter referred to as peripheral region) of the semiconductor layer 20. An embodiment of surrounding the pixel region 20-1 with the separation region will be described later. With the separation region having a multi-stage configuration using the first separation region 24 and the second separation region 25, a deep separation region that extends from the first plane 21 to the second plane 22 of the semiconductor layer 20 can be configured without forming each separation region to be thick. An element (not illustrated) that configures a signal processing circuit for processing signals from the photoelectric conversion element 23, for example, is formed in the peripheral region 20-2 separated from the pixel region 20-1 where the photoelectric conversion element 23 is formed.

A protective film 30 is disposed on the first plane 21 of the semiconductor layer 20. The protective film 30 is composed, for example, of a silicon dioxide film or a silicon nitride film A color filter 31 is arranged on the protective film 30. Each color filter 31 transmits only one of the colors of red (R), green (G), or blue (B), for example. The color filter 31 is arranged to correspond to the respective photoelectric conversion element 23.

A micro lens 32 is arranged on the color filter 31. The micro lens 32 has a spherical surface (or curved surface), and collects the incident light to the photoelectric conversion element 23.

According to the present embodiment, the separation region that extends from the first plane 21 to the second plane 22 of the semiconductor layer 20 where the photoelectric conversion element 23 is formed, for example, is formed by the multi-stage configuration by the first separation region 24 and the second separation region 25. With the multi-stage configuration of the first separation region 24 and the second separation region 25, the separation region that passes through the semiconductor layer 20 can be formed without forming the respective separation regions to be thick or deep. For example, when forming the second separation region 25 by embedding the insulating film in an opening (not illustrated), the manufacturing is facilitated since there is no need to form a deep opening. Furthermore, the insulating property between the pixel region 20-1 formed with the photoelectric conversion element 23 and the peripheral region 20-2, for example, can be enhanced by separating the regions with the separation region that extends from the first plane 21 to the second plane 22 of the semiconductor layer 20. The leak current between the regions thus can be reduced.

With the multi-stage configuration of the first separation region 24 and the second separation region 25, each of the plurality of photoelectric conversion elements 23 can be separated. Similarly, in a so-called FSI (Front Surface Illumination) type CMOS image sensor of entering light from the front surface side of the semiconductor substrate, the pixel region (not illustrated) and the peripheral region (not illustrated), or the photoelectric conversion elements (not illustrated) can be separated with the multi-stage configuration of the first separation region 24 and the second separation region 25. At the connecting section 200 where the first separation region 24 and the second separation region 25 make contact, the widths of the first separation region 24 and the second separation region 25 may be made the same. The first separation region 24 and the second separation region 25 may be, for example, configured with an oxide film. Alternatively, if the semiconductor layer 20 is an N conductivity type, for example, boron, which is a P conductivity type dopant, may be injected to form the second separation region 25 of P conductivity type. An electrical separation is obtained by the P/N junction formed between the semiconductor layer 20 and the second separation region 25. The embodiments of the method for manufacturing the semiconductor device will be described later.

FIG. 2 is a perspective view schematically illustrating a part of a cross-sectional structure of the semiconductor device 1 of the first embodiment. In order to illustrate the arrangement relationship of the separation region (24, 25) and the pixel region 20-1, the protective film 30, the color filter 31, and the micro lens 32 formed on the surface of the semiconductor layer 20 are omitted.

The first separation region 24 and the second separation region 25 are brought into contact at the connecting section 200 to configure the separation region of multi-stage configuration. The widths of the cross-section orthogonal to the longitudinal direction of the first separation region 24 and the second separation region 25 are such that the width of the second separation region 25 is narrower. The separation region configured by the first separation region 24 and the second separation region 25 is formed to surround the periphery of the pixel region 20-1 where the photoelectric conversion element 23 is formed. The pixel region 20-1 thus can be separated from the peripheral region 20-2. Since the first separation region 24 and the second separation region 25 configure the separation region that extends from the first plane 21 to the second plane 22 of the semiconductor layer 20, the insulating property between the pixel region 20-1 and the peripheral region 20-2 can be enhanced.

### Second Embodiment

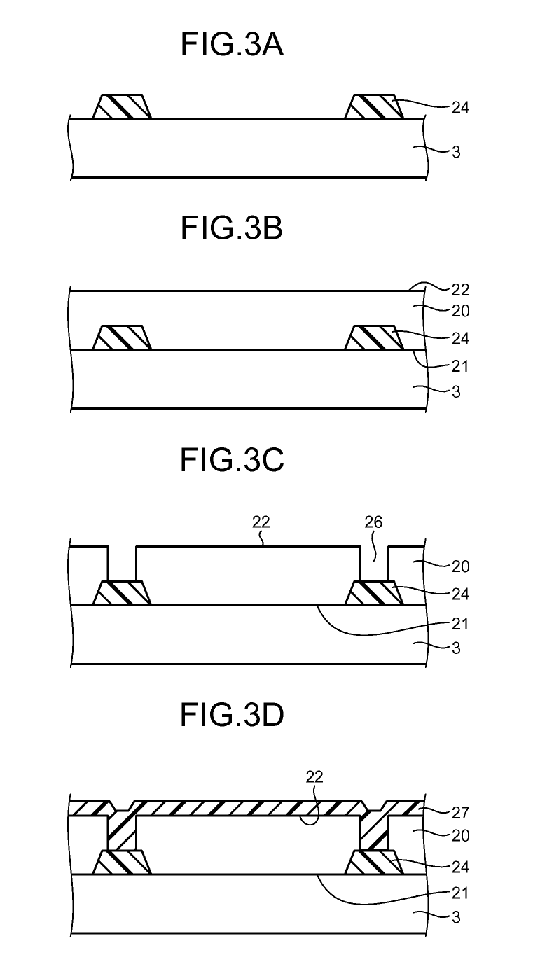

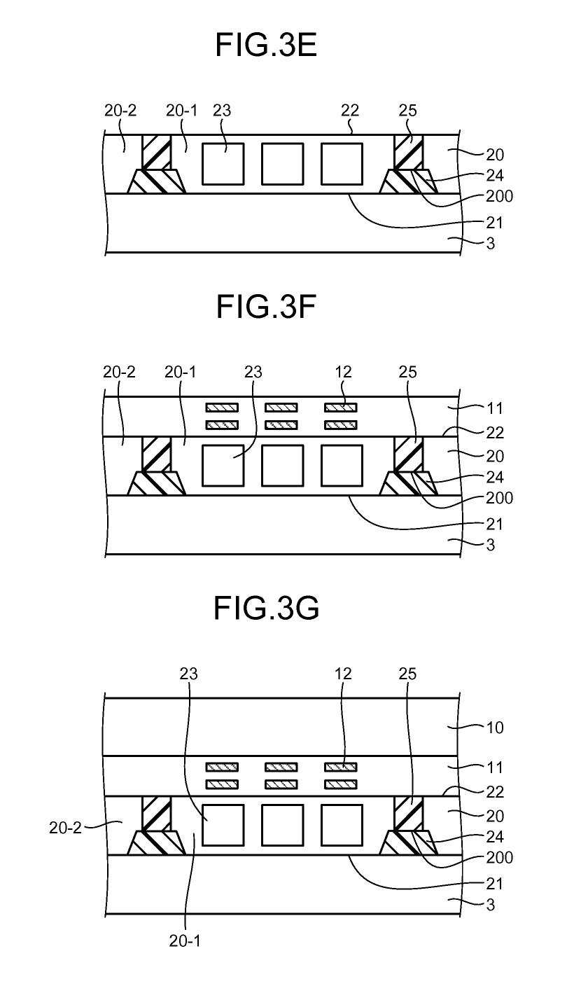

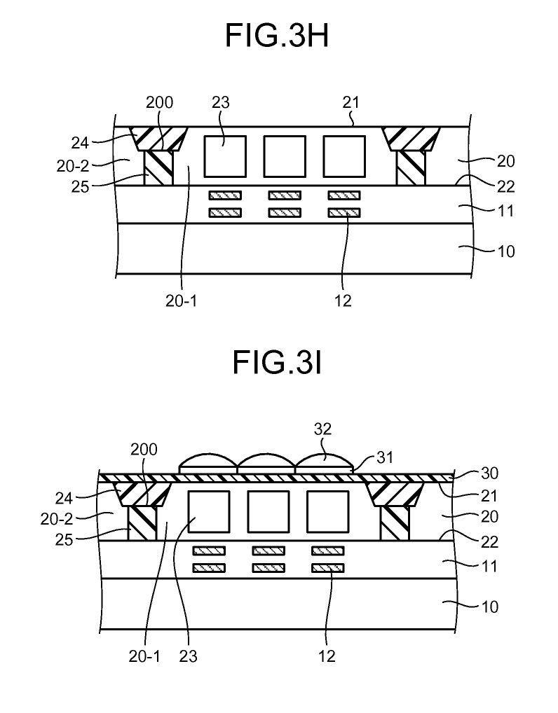

One embodiment of the method for manufacturing the semiconductor device 1 will now be described using FIGS. 3A to 3I. The same reference numerals are denoted on the configuring elements corresponding to the embodiment described above. The semiconductor substrate 3 is prepared. The semiconductor substrate 3 is, for example, a silicon substrate. The first separation region 24 is selectively formed on the front surface of the semiconductor substrate 3 (FIG. 3A). The first separation region 24 is formed by, for example, forming the silicon dioxide film on the semiconductor substrate 3 by the CVD (Chemical Vapor Deposition), and then patterning the silicon dioxide film by the RIE (Reactive Ion Etching) or the wet etching. The front surface of the semiconductor substrate 3 may be oxidized to form the silicon dioxide film, and thereafter, the silicon dioxide film may be patterned to form the first separation region 24. The first separation region 24 has, for example, a trapezoidal cross-section in which the width is wide on the semiconductor substrate 3 side and the width becomes narrower toward the upper side. The cross-sectional shape of the first separation region 24 can be controlled by adjusting the etching conditions in the patterning. The first separation region 24 has, for example, a thickness of several dozen nm (nanometer) to several hundred nm.

The semiconductor layer 20 is formed on the front surface of the semiconductor substrate 3 with the first separation region 24 selectively formed (FIG. 3B). The semiconductor layer 20 is formed by epitaxial growing. For example, the semiconductor layer 20 is formed by the CVD. The semiconductor layer 20 has a film thickness of about 5 μm (micrometer), and includes the first plane 21 and the second plane 22.

An opening 26 is formed in the semiconductor layer 20 at a position corresponding to the first separation region 24 (FIG. 3C). The opening 26 is extended from the second plane 22 of the semiconductor layer 20 toward the first plane 21 until reaching the first separation region 24. For example, the opening 26 can be formed by the RIE.

An insulating film 27 including the silicon dioxide film, for example, is formed on the second plane 22 of the semiconductor layer 20, and the opening 26 is filled with the insulating film 27 (FIG. 3D). The insulating film 27 is, for example, formed by the CVD.

The insulating film 27 on the second plane 22 of the semiconductor layer 20 is removed until the second plane 22 is exposed by the CMP (Chemical Mechanical Polishing), for example. The insulating film 27 remaining in the opening 26 forms the second separation region 25. The first separation region 24 and the second separation region 25 can form the separation region that extends from the first plane 21 to the second plane 22 of the semiconductor layer 20. The first separation region 24 and the second separation region 25 are brought into contact at the connecting section 200 to configure the separation region of multi-stage configuration.

Steps called FEOL (Front End of Line) such as a lithography step, a film forming step, an etching step, an ion injecting step, and the like are repeated on the semiconductor layer 20 to form the photoelectric conversion element 23 in the pixel region 20-1 surrounded by the first separation region 24 and the second separation region 25, for example. At the same time, an element (not illustrated) configuring a logic circuit, for example, is formed in the peripheral region 20-2 adjacent to the periphery of the pixel region 20-1 (FIG. 3E).

Next, the insulating film 11 formed with the wiring 12 for electrical connection is formed in steps called BEOL (Back End of Line) (FIG. 3F). The wiring 12 formed in the insulating film 11 can, for example, be configured with a Cu wiring having a damascene structure. The insulating film 11 covering the wiring 12 is, for example, an oxide film formed with the TEOS (Tetra Ethyl Ortho Silicate) as the raw material.

The supporting substrate 10 is formed on the insulating film 11 (FIG. 3G). The supporting substrate 10 is, for example, a semiconductor substrate. The supporting substrate 10 is bonded to the insulating film 11, for example. In the bonding step, a step of washing the bonding surface, a step of activating the bonding surface, and the like are carried out. Thereafter, the supporting substrate 10 is aligned with the insulating film 11 and then pressurized to be bonded thereto. Subsequently, an annealing process is carried out to enhance the bonding strength.

Then, the semiconductor substrate 3 is removed (FIG. 3H). For the sake of convenience of explanation, the top and bottom are interchanged. In the removing step of the semiconductor substrate 3, for example, the removal is carried out by combining the wet etching and the CMP. In other words, after removing the semiconductor substrate 3 to a certain extent through the wet etching, the semiconductor substrate 3 is continuously removed by the CMP. In the present embodiment, the first separation region 24 configured by the silicon dioxide film, for example, is formed in the semiconductor layer 20. Therefore, when removed using the CMP, the first separation region 24 functions as an etching stopper layer. In other words, when the removal of the semiconductor substrate 3 is terminated and a polishing pad (not illustrated) of the CMP reached the surface of the first separation region 24, for example, change in a drive current value of a polishing device (not illustrated) can be detected to determine a polishing terminating point. For example, assuming the cross-sectional shape of the first separation region 24 is a trapezoidal shape, the change amount of the drive current value of when the removal of the semiconductor substrate 3 is terminated can be increased by widening the area of the first separation region 24 that makes contact with the polishing pad of the CMP.

The protective film 30 is continuously formed on the first plane 21 of the semiconductor layer 20. The protective film 30 can be configured with the silicon dioxide film or the silicon nitride film, for example. The protective film 30 is formed by the CVD, for example. The color filter 31 and the micro lens 32 are formed on the protective film 30 (FIG. 3I).

According to the method for manufacturing the semiconductor device of the present embodiment, the first separation region 24 formed in the semiconductor layer 20 where the photoelectric conversion element 23 is formed, for example, functions as the etching stopper layer. The first separation region 24 is formed before forming the semiconductor layer 20. Therefore, the thickness of the semiconductor layer 20 can be accurately controlled by polishing the semiconductor substrate 3 to be removed until the surface of the first separation region 24 appears. Thus, the variation in the film thickness of the semiconductor layer 20 among the semiconductor devices can be suppressed. As the accuracy of the film thickness of the semiconductor layer 20 formed with the photoelectric conversion element 23, and the like can be enhanced, the variation in the film thickness of the photoelectric conversion region, where the photoelectric conversion element 23 is formed, can be suppressed, and the variation in the sensitivity of the photoelectric conversion element 23 can be suppressed. The separation region that extends from the first plane 21 to the second plane 22 of the semiconductor layer 20 is formed by the multi-stage configuration of the first separation region 24 and the second separation region 25. According to the multi-stage configuration, the opening 26 for providing the second separation region 25 does not need to be formed deep, and hence the formation of the opening 26 for the second separation region 25 is facilitated. The regions are separated by the separation region (24, 25) that extends from the first plane 21 to the second plane 22 of the semiconductor layer 20, so that the insulating property of the regions (20-1, 20-2) is enhanced.

### Third Embodiment

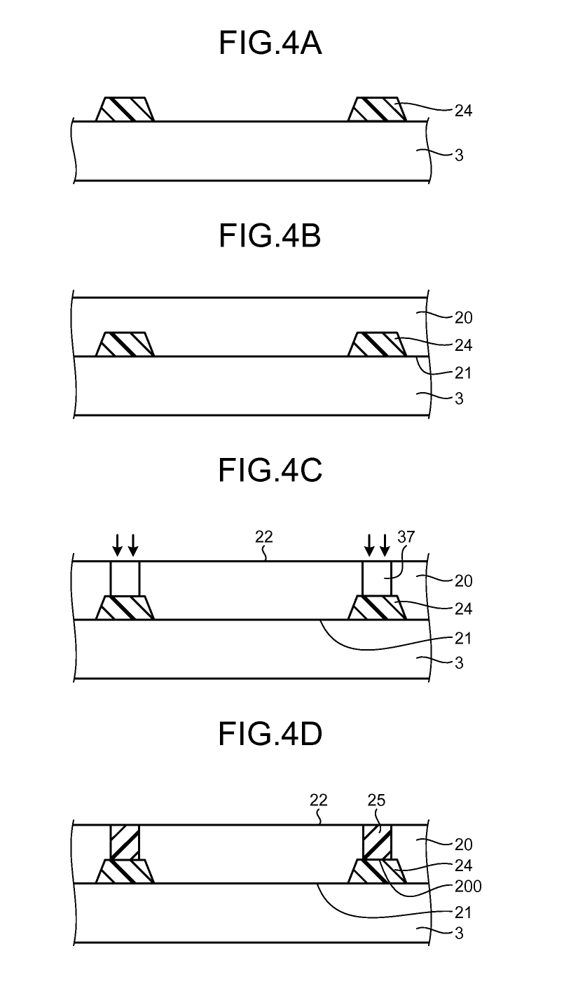

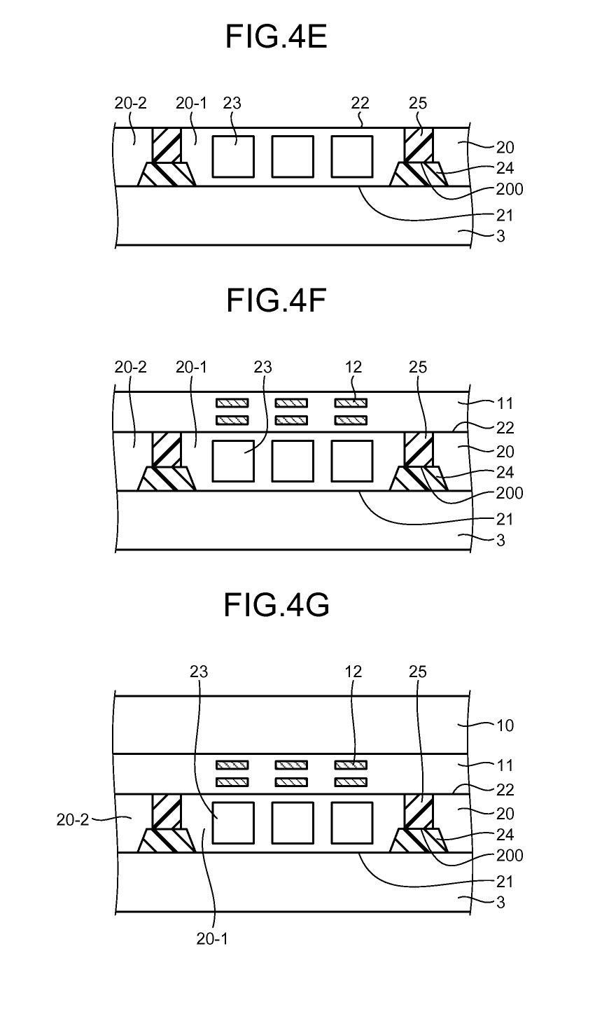

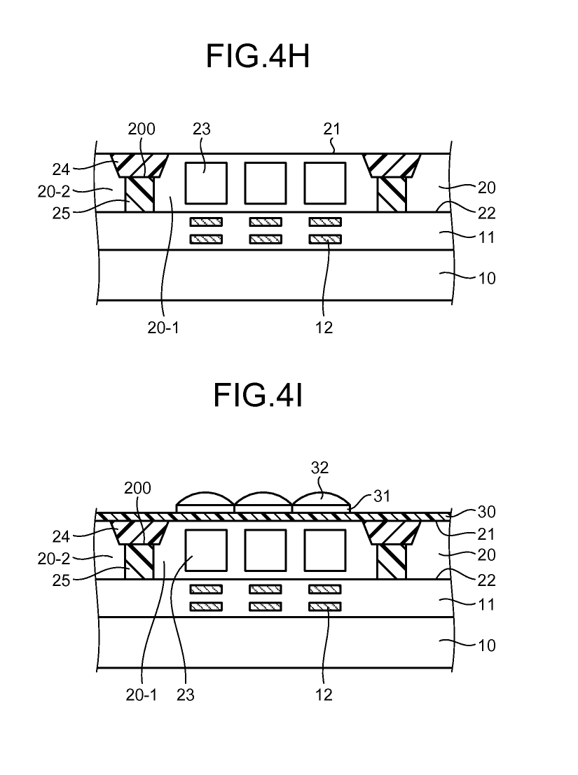

Another embodiment of the method for manufacturing the semiconductor device 1 will now be described using FIGS. 4A to 4I. The same reference numerals are denoted on the configuring elements corresponding to the embodiments described above. In the manufacturing method of the present embodiment, the method for forming the separation region to be formed in the semiconductor layer 20 is different.

The semiconductor substrate 3 is prepared. The first separation region 24 is selectively formed on the front surface of the semiconductor substrate 3 (FIG. 4A). The first separation region 24 is formed by, for example, forming the silicon dioxide film on the semiconductor substrate 3 by the CVD, and patterning the silicon dioxide film by the RIE or the wet etching. The front surface of the semiconductor substrate 3 may be oxidized to form the silicon dioxide film, and thereafter patterned. The first separation region 24 has, for example, a trapezoidal cross-section in which the width is wide on the semiconductor substrate 3 side and the width becomes narrower toward the upper side. The cross-sectional shape of the first separation region 24 can be controlled by adjusting the etching conditions in the patterning. The first separation region 24 has, for example, a thickness of several dozen nm (nanometer) to several hundred nm.

The semiconductor layer 20 is formed on the front surface of the semiconductor substrate 3 selectively formed with the first separation region 24 (FIG. 4B). The semiconductor layer 20 is formed using the CVD, for example. The semiconductor layer 20 has a film thickness of about 5 μm, and includes the first plane 21 and the second plane 22.

Oxygen ions are injected to a position 37 corresponding to the first separation region 24 from the second plane 22 side of the semiconductor layer 20 (FIG. 4C).

Thereafter, the annealing process is carried out to form the second separation region 25 configured by the silicon dioxide film (FIG. 4D). The second separation region 25 that makes contact with the first separation region 24 from the second plane 22 side of the semiconductor layer 20 can be formed by the adjustment of the injecting conditions of the oxygen ion, for example, the amount of oxygen ions to inject, the acceleration voltage, and the like. The first separation region 24 and the second separation region 25 can form the separation region that extends from the first plane 21 to the second plane 22 of the semiconductor layer 20. The first separation region 24 and the second separation region 25 are brought into contact at the connecting section 200 to configure the separation region having the multi-stage configuration.

The FEOL steps such as the lithography step, the film forming step, the etching step, the ion injecting step, and the like are repeated on the semiconductor layer 20 to form the photoelectric conversion element 23 in the pixel region 20-1 surrounded by the first separation region 24 and the second separation region 25, for example. At the same time, an element (not illustrated) configuring a logic circuit, for example, is formed in the peripheral region 20-2 adjacent to the periphery of the pixel region 20-1 (FIG. 4E).

Next, the insulating film 11 formed with the wiring 12 for electrical connection is formed in the BEOL step (FIG. 4F). The wiring 12 formed in the insulating film 11 can, for example, be configured with a Cu wiring having a damascene structure. The insulating film 11 covering the wiring 12 is, for example, an oxide film formed with the TEOS as the raw material.

The supporting substrate 10 is formed on the insulating film 11 (FIG. 4G). The supporting substrate 10 is, for example, a semiconductor substrate, and is formed by the lamination with the insulating film 11. In the laminating step, a step of washing the bonding surface, a step of activating the bonding surface, and the like are carried out in advance. Thereafter, the supporting substrate 10 is aligned with the insulating film 11 and then pressurized to be laminated thereto. Subsequently, the annealing process is carried out to enhance the bonding strength.

Subsequently, the semiconductor substrate 3 is removed (FIG. 4H). For the sake of convenience of explanation, the top and bottom are interchanged. In the removing step of the semiconductor substrate 3, for example, the removal is carried out by combining the wet etching and the CMP. In other words, after removing the semiconductor substrate 3 to a certain extent by the wet etching, the semiconductor substrate 3 is continuously removed by the CMP. In the present embodiment, the first separation region 24 configured by the silicon dioxide film, for example, is formed on the first plane 21 side of the semiconductor layer 20. Therefore, when removing the semiconductor substrate 3 using the CMP, the first separation region 24 functions as an etching stopper layer. In other words, change that arises when the polishing of the semiconductor substrate 3 is terminated and a polishing pad (not illustrated) of the CMP reached the surface of the first separation region 24, for example, change in a drive current value of the polishing device (not illustrated) is detected to determine the polishing terminating point.

The protective film 30 is continuously formed on the first plane 21 of the semiconductor layer 20. The protective film 30 can be configured with the silicon dioxide film or the silicon nitride film, for example. The protective film 30 is formed by the CVD, for example. The color filter 31 and the micro lens 32 are formed on the protective film 30 (FIG. 4I).

According to the method for manufacturing the semiconductor device 1 of the present embodiment, the first separation region 24 formed in the semiconductor layer 20 where the photoelectric conversion element 23 is formed, for example, functions as the etching stopper layer. The first separation region 24 is formed in advance when forming the semiconductor layer 20. Therefore, the thickness of the semiconductor layer 20 can be accurately controlled by polishing until the surface of the first separation region 24 appears to remove the semiconductor substrate 3. Thus, the variation in the film thickness of the photoelectric conversion region where the photoelectric conversion element 23 is formed can be suppressed, and the variation in the sensitivity of the photoelectric conversion element 23 can be suppressed. By multi-stage configuration of the first separation region 24 and the second separation region 25, the separation region that passes through the semiconductor layer 20 is configured. Since the oxygen ions for forming the second separation region 25 do not need to be deeply injected due to the multi-stage configuration, the manufacturing is facilitated. Furthermore, the spread of the oxygen ions in the lateral direction can be suppressed since the oxygen ions do not need to be deeply injected. Thus, a region where the semiconductor element can be formed can be widened. The insulating property between the regions can be enhanced by separating the regions (20-1, 20-2) with the separation region (24, 25) that extends from the first plane 21 to the second plane 22 of the semiconductor layer 20. The second separation region 25 may be formed by injecting a dopant of a predetermined conductivity type. For example, if the semiconductor layer 20 is an N conductivity type, boron (B) ion, which is a P conductivity type dopant, may be injected to form the second separation region 25 of P conductivity type. A configuration that can be electrically separated by the P/N junction formed between the semiconductor layer 20 and the second separation region 25 is provided.

The configuration of the separation region having the multi-stage configuration of the first separation region 24 and the second separation region 25 can be applied to a so-called FSI type CMOS image sensor in which the light enters from the front side of the semiconductor substrate. For example, in the formation of the epitaxial layer (not illustrated) that forms the photoelectric conversion element (not illustrated) of the FSI type CMOS image sensor, the first separation region (not illustrated) is formed in advance in the front surface of the semiconductor substrate (not illustrated) that forms the epitaxial layer, and after the epitaxial layer is formed, the second separation region (not illustrated) from the surface of the epitaxial layer facing the semiconductor substrate to the first separation region is formed in correspondence with the first separation region, so that the separation region having the multi-stage configuration that extends from the first plane to the second plane of the epitaxial layer can be similarly formed. According to the separation region having the multi-stage configuration using the first separation region and the second separation region, the deep separation region that extends from the first plane to the second plane of the epitaxial layer can be formed without forming the respective separation regions thick, and thus the manufacturing of the separation region is facilitated. Furthermore, as described above, the oxygen ions do not need to be deeply injected when forming the second separation region by injecting the oxygen ions, so that the spread of the oxygen ions in the lateral direction can be suppressed and the region where the semiconductor element can be formed can be widened.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer including a first plane and a second plane facing the first plane, and being formed with a semiconductor element; and
a separation region formed to extend from the first plane to the second plane of the semiconductor layer, and to surround a region where the semiconductor element is formed; wherein
the separation region includes,
a first separation region formed from the first plane of the semiconductor layer toward an interior of the semiconductor layer, and
a second separation region formed from the second plane of the semiconductor layer to the first separation region.

2. The semiconductor device according to claim 1, wherein the semiconductor element is a photoelectric conversion element.

3. The semiconductor device according to claim 1, further comprising an insulating film configured to make contact with the second plane of the semiconductor layer and interiorly formed with a wiring.

4. The semiconductor device according to claim 2, further comprising an insulating film configured to make contact with the second plane of the semiconductor layer and interiorly formed with a wiring.

5. The semiconductor device according to claim 1, wherein a width of the second separation region is narrower than a width of the first separation region in a cross-section orthogonal to a longitudinal direction of the first separation region and the second separation region.

6. The semiconductor device according to claim 2, wherein a width of the second separation region is narrower than a width of the first separation region in a cross-section orthogonal to a longitudinal direction of the first separation region and the second separation region.

7. The semiconductor device according to claim 3, wherein a width of the second separation region is narrower than a width of the first separation region in a cross-section orthogonal to a longitudinal direction of the first separation region and the second separation region.

8. The semiconductor device according to claim 1, wherein the first separation region has a shape of being wide on the first plane side and becoming narrower toward the interior of the semiconductor layer in the cross-section.

9. The semiconductor device according to claim 2, wherein the first separation region has a shape of being wide on the first plane side and becoming narrower toward the interior of the semiconductor layer in the cross-section.

10. The semiconductor device according to claim 3, wherein the first separation region has a shape of being wide on the first plane side and becoming narrower toward the interior of the semiconductor layer in the cross-section.

11. A method for manufacturing a semiconductor device comprising the steps of:
selectively forming a first separation region on a surface of a semiconductor substrate;
forming a semiconductor layer including a first plane that makes contact with the surface of the semiconductor substrate and a second plane facing the first plane on the surface of the semiconductor substrate where the first separation region is formed;
selectively forming a second separation region from the second plane of the semiconductor layer to the first separation region;
forming an insulating film on the semiconductor layer;
forming a supporting substrate on the insulating film; and
removing the semiconductor substrate after forming the supporting substrate.

12. The method for manufacturing the semiconductor device according to claim 11, wherein the step of removing the semiconductor substrate further includes a step of polishing the semiconductor substrate until a surface of the first separation region is exposed.

13. The method for manufacturing the semiconductor device according to claim 11, wherein the second separation region is formed by injecting ions.

14. The method for manufacturing the semiconductor device according to claim 12, wherein the second separation region is formed by injecting ions.

15. The method for manufacturing the semiconductor device according to claim 11, wherein the second separation region is formed by selectively embedding an insulator from the second plane side of the semiconductor layer.

16. The method for manufacturing the semiconductor device according to claim 12, wherein the second separation region is formed by selectively embedding an insulator from the second plane side of the semiconductor layer.

17. The method for manufacturing the semiconductor device according to claim 11, wherein the first separation region has a shape in which a width on the semiconductor substrate side is wide and the width becomes narrower away from the semiconductor substrate in a cross-section orthogonal to a longitudinal direction.

18. The method for manufacturing the semiconductor device according to claim 12, wherein the first separation region has a shape in which a width on the semiconductor substrate side is wide and the width becomes narrower away from the semiconductor substrate in a cross-section orthogonal to a longitudinal direction.

19. The method for manufacturing the semiconductor device according to claim 11, wherein a semiconductor region is formed in the semiconductor layer, a periphery of the semiconductor region being surrounded by the first separation region and the second separation region, and a photoelectric conversion element being formed in the semiconductor region.

20. The method for manufacturing the semiconductor device according to claim 12, wherein a semiconductor region is formed in the semiconductor layer, a periphery of the semiconductor region being surrounded by the first separation region and the second separation region, and a photoelectric conversion element being formed in the semiconductor region.
